(19) United States
(12) Patent Application Publication
(10) Pub. No.: US 2015/0337460 A1
(43) Pub. Date: Nov. 26, 2015

(54) SUBSTRATE-PROCESSING DEVICE

(71) Applicant: EUGENE TECHNOLOGY CO., LTD., Yongin-si Gyeonggi-do (KR)

(72) Inventors: Il-Kwang YANG, Gyeonggi-do (KR); Byoung-Gyu SONG, Gyeonggi-do (KR); Kyong-Hun KIM, Gyeonggi-do (KR); Yong-Ki KIM, Chungcheongnam-do (KR); Yang-Sik SHIN, Gyeonggi-do (KR)

(73) Assignee: EUGENE TECHNOLOGY CO., LTD., Gyeonggi-do (KR)

(21) Appl. No.: 14/652,986

(22) PCT Filed: Jan. 9, 2014
(86) PCT No.: PCT/KR2014/000249

§ 371 Date: Jun. 17, 2015

(30) Foreign Application Priority Data
Jan. 15, 2013 (KR) 10-2013-0004539

(51) Int. Cl. C30B 35/00

(52) U.S. Cl. CPC C30B 35/005

(57) ABSTRACT

Provided is a substrate processing apparatus. The substrate processing apparatus includes a process chamber in which a process with respect to a substrate is performed, a preliminary chamber connected to the process chamber, the preliminary chamber having a passage through which the substrate is accessed, a blocking plate partitioning the inside of the preliminary chamber into a holding region and a transfer region, a substrate holder on which at least one substrate is loaded, the substrate holder being switchable into a loading position in which the substrate holder is disposed on the holding region and a process position in which the substrate holder is disposed on the process chamber, a substrate transfer unit transferring the substrate holder from the loading position to the process position, the substrate transfer unit including a transfer arm connected to the substrate holder and a driver operating the transfer arm, a gas supply port supplying an inert gas into the preliminary chamber, and a lower exhaust port connected to the transfer region and disposed above the gas supply port to exhaust the inside of the preliminary chamber. The lower exhaust port is disposed closer to a bottom surface of the preliminary chamber than a top surface of the preliminary chamber.

### TECHNICAL FIELD

The present invention disclosed herein relates to a substrate processing apparatus, and more particularly, to a substrate processing apparatus including a lower exhaust port for exhausting the inside of a preliminary chamber.

### BACKGROUND ART

Typically, a selective epitaxy process involves deposition reaction and etching reaction. The deposition and etching reaction may occur in a polycrystalline layer and an epitaxial layer at relatively different reaction rates at the same time. During the deposition process, an epitaxial layer is formed on a monocrystalline surface while an existing polycrystalline layer and/or amorphous layer are(is) deposited on at least one second layer. However, the deposited polycrystalline layer is generally etched at a rate greater than that of the epitaxial layer. Thus, as the etching gas changes in concentration, a net selective process results in deposition of an epitaxy material or deposition of a polycrystalline material, which is limited or not. For example, the selective epitaxy process may result in the formation of an epilayer formed of a silicon-containing material on a surface of the monocrystalline silicon without allowing the deposited material to remain on a spacer.

In general, the selective epitaxy process may have several limitations. To maintain selectivity during the epitaxy process, a precursor has to be adjusted and controlled in chemical concentration and reaction temperature over the deposition process. If the silicon precursor is not sufficiently supplied, the etching reaction may be activated to reduce the whole processing rate. Also, harmful over etching of substrate features may occur. If an etchant precursor is not sufficiently supplied, the deposition reaction may result in reduction in selectivity with respect to the formation of monocrystalline and polycrystalline materials over the substrate surface. Also, the typical selective epitaxy process generally requires a high reaction temperature of about 800° C., for example, a reaction temperature of about 1,000° or more. The high temperature is not desirable during a manufacturing process due to possible uncontrolled nitridation reaction and thermal budget on the substrate surface.

### DISCLOSURE

### Technical Problem

The present invention provides a substrate processing apparatus that is capable of effectively exhausting the inside of a preliminary chamber.

The present invention also provides a substrate processing apparatus that is capable of minimizing contamination of a substrate within a preliminary chamber.

Further another object of the present invention will become evident with reference to following detailed descriptions and accompanying drawings.

### Technical Solution

Embodiments of the present invention provide substrate processing apparatuses including: a process chamber in which a process with respect to a substrate is performed; a preliminary chamber connected to the process chamber, the preliminary chamber having a passage through which the substrate is accessed; blocking plate partitioning the inside of the preliminary chamber into a holding region and a transfer region; a substrate holder on which at least one substrate is loaded, the substrate holder being switchable into a loading position in which the substrate holder is disposed on the holding region and a process position in which the substrate holder is disposed on the process chamber; a substrate transfer unit transferring the substrate holder from the loading position to the process position, the substrate transfer unit including a transfer arm connected to the substrate holder and a driver operating the transfer arm; a gas supply port supplying an inert gas into the preliminary chamber; and a lower exhaust port connected to the transfer region and disposed above the gas supply port to exhaust the inside of the preliminary chamber, wherein the lower exhaust port is disposed closer to a bottom surface of the preliminary chamber than a top surface of the preliminary chamber.

In some embodiments, the blocking plate may have an upper exhaust hole positioned higher than that of the substrate holder and a lower exhaust hole positioned lower than that of the substrate holder in a state where the substrate holder is positioned at the loading position, and the holding region and the transfer region may communicate with each other through the upper exhaust hole and the lower exhaust hole.

In other embodiments, the gas supply port may be positioned lower than that of the substrate holder in the state where the substrate holder is positioned at the loading position.

In still other embodiments, the substrate processing apparatuses may further include an upper exhaust port connected to the process chamber to exhaust the inside of the process chamber and a main exhaust line connected to the upper exhaust port and the lower exhaust port.

### Advantageous Effects

According to the embodiment of the present invention, the preliminary chamber may be effectively exhausted, and the contamination of the substrate within the preliminary chamber may be minimized

### DESCRIPTION OF DRAWINGS

FIG. 1 is a schematic view of a substrate processing apparatus according to an embodiment of the present invention;

FIG. 2 is a view of a state in which a substrate holder of FIG. 1 is switched to a process position; and

FIG. 3 is a view illustrating a gas flow within a preliminary chamber of FIG. 1.

### BEST MODE

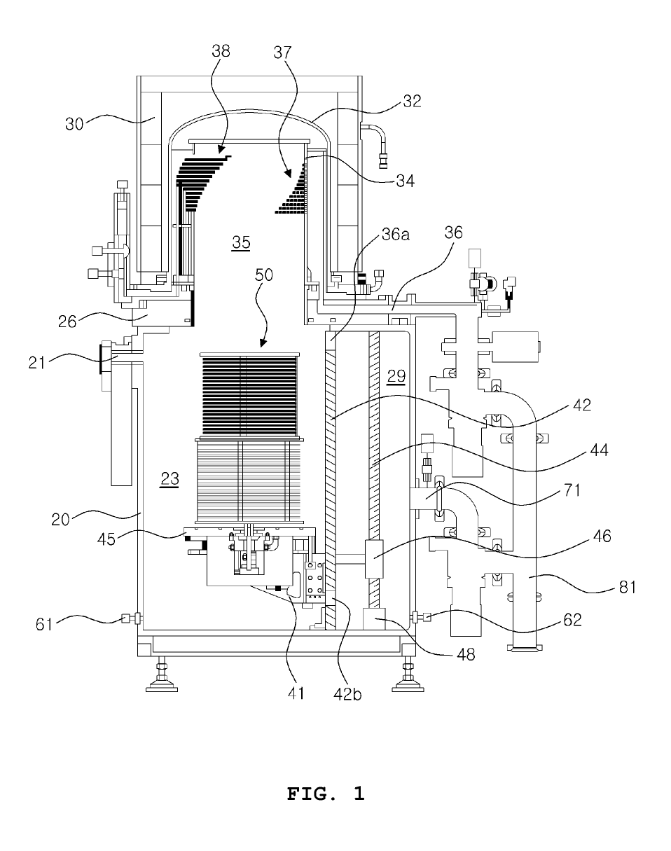

Hereinafter, exemplary embodiments of the present invention will be described in detail with reference to FIGS. 1 to 3. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

Although the epitaxial process is described below as an example, the present invention may be applicable to various semiconductor manufacturing processes in addition to the epitaxial process.

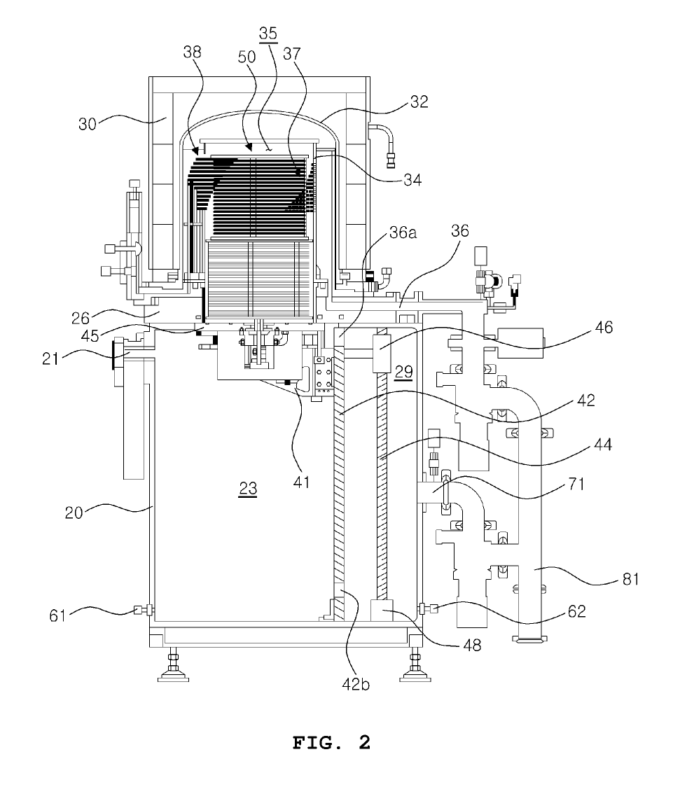

FIG. 1 is a schematic view of a substrate processing apparatus according to an embodiment of the present invention, and FIG. 2 is a view of a state in which a substrate holder of FIG. 1 is switched to a process position. Referring to FIG. 1, a substrate processing apparatus includes a lower chamber 20 having an opened upper portion. Also, the lower chamber has a passage 21 through which a substrate is transferred. The substrate may be loaded into the lower chamber 20 through the passage 21. A gate valve (not shown) may be installed outside the passage 21, and the passage 21 may be opened or closed by the gate valve.

A substrate holder 50 accommodates a plurality of substrates. Here, the plurality of substrates may be vertically loaded on the substrate holder 50. As illustrated in FIG. 1, when the substrate holder 50 is positioned in preliminary chambers 23 and 29 of the lower chamber 20 (or at a “loading position”), the substrate may be loaded within the substrate holder 50. As described below, the substrate hole may be elevatable. When a substrate is loaded on a slot of the substrate holder 50, the substrate holder 50 ascends to load a substrate on the next slot of the substrate holder 50. When the substrates are completely loaded on the substrate holder 50, the substrate holder 50 may move into a process chamber 35 (or to the “process position”) to perform an epitaxial process within the process chamber 35 as illustrated in FIG. 2.

A base 45 is disposed on a lower portion of the substrate holder 50 and is elevated together with the substrate holder 50. When the substrate holder 50 is switched to the process position, the base 45 is closely attached to a bottom surface of a flange 26 to block the process chamber 35 from the outside as illustrated in FIG. 2. The base 45 may be formed of ceramic or quartz or a material coated ceramic on a metal to prevent heat within the process chamber 35 from being transferred into the preliminary chambers 23 and 29 when the process proceeds.

A blocking plate 42 stands up within the preliminary chambers 23 and 29 to partition the preliminary chambers 23 and 29 into a holding region 23 and a transfer region 29. The blocking plate 42 has an upper exhaust hole 42a and a lower exhaust hole 42b which respectively communicate with the holding region 23 and the transfer region 29. The upper exhaust hole 42a is defined above the substrate holder 50 positioned at the loading position, and the lower exhaust hole 42b is defined below the substrate holder 50 positioned at the loading position.

The substrate holder 50 is disposed in the holding region 23, and a driver for elevating the substrate holder 50 is disposed in the transfer region 29. A transfer arm 41 is connected to the driver through a moving slot (not shown) having a narrow and long shape and defined in the blocking plate 42 in a state where the transfer arm 41 is connected to the base 45. The driver includes an elevation screw 44, a bracket 46, and a driving motor 48. The bracket 46 is disposed on the elevation screw 44 to ascend or descend by rotation of the elevation screw 44, and the driving motor 48 rotates the elevation screw 44.

The lower chamber 20 includes a lower exhaust port 71. Here, the lower exhaust port 71 is disposed closer to a bottom surface than a top surface of the preliminary chambers 23 and 29. The lower exhaust port 71 is disposed in the transfer region 29 and connected to an exhaust line 81. The insides of the preliminary chambers 23 and 29 may be exhausted through the lower exhaust port 71 and the exhaust line 81.

Gas supply ports 61 and 62 are connected to the preliminary chambers 23 and 29 to supply an inert gas into the preliminary chambers 23 and 29, respectively. The gas supply port 61 supplies the inert gas (e.g., such as nitrogen gas) into the holding region 23, and the gas supply port 62 supplies the inert gas into the transfer region 29.

An internal reaction tube 34 and an external reaction tube 32 are disposed above the flange 26, and the flange 26 is disposed on an upper portion of the lower chamber 20. The process chamber 35 defined in the internal reaction tube 34 and the preliminary chambers 23 and 29 defined inside the lower chamber 20 communicate with each other through an opening defined in a central portion of the flange 26. As described above, when the substrates are completely loaded on the substrate holder 50, the substrate holder 50 may be transferred into the process chamber 35 through the opening.

The internal reaction tube 34 is disposed within the external reaction tube 32 to perform the epitaxial process on the substrates within the process chamber 35. The internal reaction tube 34 may have a diameter less than that of the external reaction tube 32 and greater than a size of the substrate holder 50. Thus, the internal reaction tube 34 may provide a minimum reaction space with respect to the substrate to minimize use of the reaction gas as well as concentrate the reaction gas onto the substrate.

Supply nozzles 38 are disposed on one side of the process chamber 35 and have different heights. The supply nozzles 38 may be connected to a reaction gas source (not shown). The reaction gas source may supply a deposition gas (a silicon gas (e.g., SiCl₄, SiHCl₃, SiH₂Cl₂, SiH₃Cl, Si₂H₆, or SiH₄) and a carrier gas (e.g., N₂ and/or H₂)) or an etching gas. The selective epitaxy process involves deposition reaction and etching reaction. Although not shown in the current embodiment, if it is required that the epitaxy layer includes a dopant, a dopant-containing gas (e.g., AsH₃, PH₃, and/or B₂H₆) may be supplied.

Similarly, exhaust nozzles 37 are disposed on the other side of the process chamber 35 and have different heights. The exhaust nozzles 37 are connected to an upper exhaust port 36, and the upper exhaust port 36 is connected to the exhaust line 81. The inside of the process chamber 35 may be exhausted through the upper exhaust port 36 and the exhaust line 81.

In the state where the substrate holder 50 is switched to the process position, each of the supply nozzles 38 and the exhaust nozzles 37 may be substantially flush with each of the substrates loaded on the substrate holder 50. The supply nozzles 38 inject the reaction gas onto the substrates loaded on the substrate holder 50, respectively. As a result, non-reaction gases and byproducts may be generated in the process chamber 35. The exhaust nozzles 37 suction the non-reaction gases and byproducts to discharge the non-reaction gases and byproducts to the outside through the exhaust line 81. A heating unit 30 may disposed to surround the external reaction tube 32. Thus, the process chamber 35 may be heated by the heating unit 30 to reach a temperature at which the epitaxial process is performable.

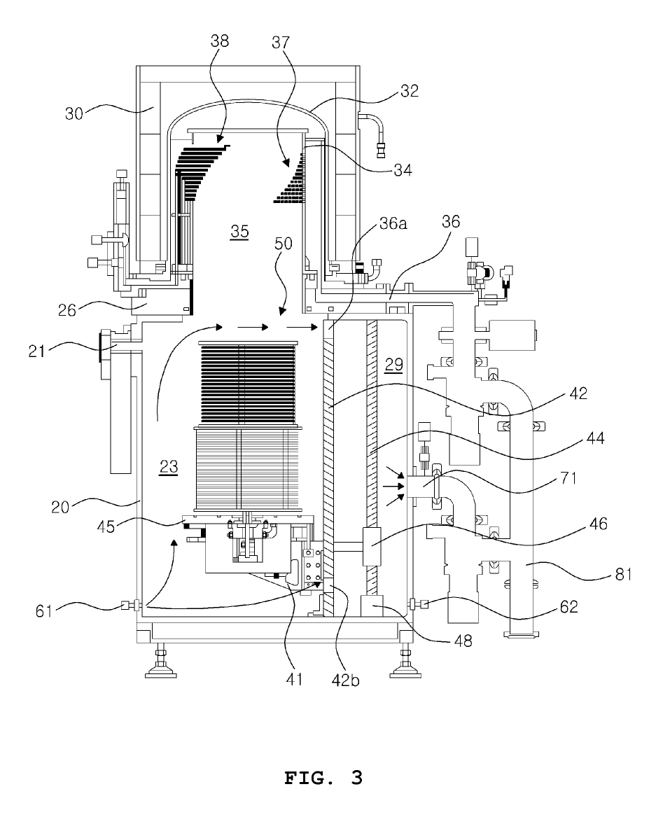

FIG. 3 is a view illustrating a gas flow within the preliminary chambers of FIG. 1. Hereinafter, a gas flow within the preliminary chambers will be described as follows with reference to FIG. 3.

As described above, the substrates are loaded on the substrate holder 50. Then, when the loading of the substrates is completed, the passage 21 is closed by the gate valve. Thereafter, the inert gas is supplied into the preliminary chambers 23 and 29 through the gas supply ports 61 and 62. Then, the insides of the preliminary chambers 23 and 29 are exhausted through the lower exhaust port 71, and thus air within the preliminary chambers 23 and 29 is purged by the inert gas. Thereafter, the substrate holder 50 is moved into the process chamber 35 that corresponds to the process position from the preliminary chambers 23 and 29 that correspond to the loading position. The base 45 is closely attached to the bottom surface of the flange 26, and the process chamber 35 and the preliminary chambers 23 and 29 are isolated from each other. Then, the epitaxial process is performed on the substrates loaded on the substrate holder 50 within the process chamber 35.

In the above-described processes, the inert gas supplied through the gas supply port 61 flows toward the upper exhaust hole 42a and the lower exhaust hole 42b to form a gas flow from the holding region 23 to the transfer region 29, thereby preventing the substrates within the holding region 23 from being contaminated by foreign substances (that are generated by the elevation screw 44 or the bracket 46) within the transfer region 29. The inert gas introduced into the transfer region 29 through the upper exhaust hole 42a and the lower exhaust hole 42b is discharged through the lower exhaust port 71.

Also, since the lower exhaust port 71 is disposed closer to the bottom surface (or the lower exhaust hole 42b) than the top surface (or the upper exhaust hole 42a) of the transfer region 29, most gas flow may be formed toward the lower exhaust hole 42b. Here, the gas may flow into the transfer region 29 together with the foreign substances precipitated on a lower portion of the holding region 23 and then is discharged through the lower exhaust port 71. Here, since the gas flow is formed toward the lower portion of the substrate holder 50, the foreign substances may be scattered by the gas flow to prevent the substrates loaded on the substrate holder 50 from being contaminated.

The gas flow formed through the upper exhaust hole 42a may purge the inside of the holding region 23 as well as serve as an air curtain for preventing heat within the process chamber 35 from being transmitted into the substrate holder 50. That is, heat transmitted from the process chamber 35 toward the holding region 23 is absorbed by the gas flowing toward the upper exhaust hole 42a. Then, the gas absorbing the heat flows into the transfer region 29 through the upper exhaust hole 42a and is discharged to the outside through the lower exhaust port 71.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention is applicable for a semiconductor manufacturing apparatus and a semiconductor manufacturing method in a various type.

1. A substrate processing apparatus comprising:
a process chamber in which a process with respect to a substrate is performed;
a preliminary chamber connected to the process chamber, the preliminary chamber having a passage through which the substrate is accessed;
a blocking plate partitioning the inside of the preliminary chamber into a holding region and a transfer region;
a substrate holder on which at least one substrate is loaded, the substrate holder being switchable into a loading position in which the substrate holder is disposed on the holding region and a process position in which the substrate holder is disposed on the process chamber;
a substrate transfer unit transferring the substrate holder from the loading position to the process position, the substrate transfer unit comprising a transfer arm connected to the substrate holder and a driver operating the transfer arm;
a gas supply port supplying an inert gas into the preliminary chamber; and
a lower exhaust port connected to the transfer region and disposed above the gas supply port to exhaust the inside of the preliminary chamber,
wherein the lower exhaust port is disposed closer to a bottom surface of the preliminary chamber than a top surface of the preliminary chamber.

2. The substrate processing apparatus of claim 1, wherein the blocking plate has an upper exhaust hole positioned higher than that of the substrate holder and a lower exhaust hole positioned lower than that of the substrate holder in a state where the substrate holder is positioned at the loading position, and
the holding region and the transfer region communicate with each other through the upper exhaust hole and the lower exhaust hole.

3. The substrate processing apparatus of claim 1, wherein the gas supply port is positioned lower than that of the substrate holder in the state where the substrate holder is positioned at the loading position.

4. The substrate processing apparatus of claim 1, further comprising an upper exhaust port connected to the process chamber to exhaust the inside of the process chamber and a main exhaust line connected to the upper exhaust port and the lower exhaust port.

5. The substrate processing apparatus of claim 2, wherein the gas supply port is positioned lower than that of the substrate holder in the state where the substrate holder is positioned at the loading position.

6. The substrate processing apparatus of claim 2, further comprising an upper exhaust port connected to the process chamber to exhaust the inside of the process chamber and a main exhaust line connected to the upper exhaust port and the lower exhaust port.
